(19) United States
(12) Patent Application Publication
(10) Pub. No.: US 2025/0017074 A1
(43) Pub. Date: Jan. 9, 2025

(54) DISPLAY APPARATUS

(71) Applicant: Samsung Display Co., Ltd., Yongin-si (KR)

(72) Inventors: Seokgyu Yoon, Yongin-si (KR); Soungwook Kim, Yongin-si (KR); Kiwoong Kim, Yongin-si (KR); Junyong Shin, Yongin-si (KR); Minsoo Choi, Yongin-si (KR)

(21) Appl. No.: 18/410,877

(22) Filed: Jan. 11, 2024

(30) Foreign Application Priority Data
Jul. 7, 2023 (KR) 10-2023-0088623

(51) Int. Cl. H10K 59/60; H10K 59/122; H10K 59/38; H10K 59/80; H10K 102/00; H10K 102/10; H10K 102/20

(52) U.S. Cl. CPC H10K 59/60; H10K 59/122; H10K 59/38; H10K 59/8792; H10K 2102/103; H10K 2102/20; H10K 2102/351

(57) ABSTRACT

A display apparatus includes: a substrate; light-emitting elements on the substrate; a first light-receiving element on the substrate and arranged next to the light-emitting elements; and a first light-receiving color filter on the first light-receiving element, wherein the first light-receiving element comprises a first transparent light-receiving electrode, a first light-absorbing layer on the first transparent light-receiving electrode, and an opposite electrode on the first light-absorbing layer, the first light-absorbing layer comprises a material that has sensitivity to light of a first, second, and third wavelengths, the first light-receiving color filter is configured to transmit the light of the first wavelength, the light of the first wavelength, second, and third wavelengths are a first one, a second one, and a third one from among green light, red light, and blue light, respectively.

### CROSS-REFERENCE TO RELATED APPLICATION

The present application claims priority to and the benefit of Korean Patent Application No. 10-2023-0088623, filed on Jul. 7, 2023, in the Korean Intellectual Property Office, the entire disclosure of which is incorporated herein by reference.

### BACKGROUND

### 1. Field

Aspects of one or more embodiments relate to a display apparatus.

### 2. Description of the Related Art

Generally, in display apparatuses, light-emitting elements, such as organic light-emitting diodes, and thin-film transistors, may be formed on a substrate, and the display apparatuses may operate by allowing the light-emitting elements to emit light. For example, each pixel of display apparatuses has a light-emitting element such as an organic light-emitting diode in which an intermediate layer including an emission layer is arranged between a pixel electrode and an opposite electrode. Display apparatuses generally control whether each pixel emits light or the degree of light emission, through thin-film transistors electrically connected to pixel electrodes. Some layers included in an intermediate layer of such a light-emitting element are commonly provided in a plurality of light-emitting elements.

Recently, applications of display apparatuses have diversified. As display apparatuses are used in various fields, the need for display apparatuses with various functions is increasing.

The above information disclosed in this Background section is only for enhancement of understanding of the background and therefore the information discussed in this Background section does not necessarily constitute prior art.

### SUMMARY

Aspects of one or more embodiments relate to a display apparatus, and for example, to a display apparatus including a light-emitting element and a light-receiving element.

Aspects of one or more embodiments include a display apparatus including a light-receiving element having relatively improved light detection characteristics.

However, the embodiments are only examples, and the scope of embodiments according to the present disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, light-emitting elements on the substrate, a first light-receiving element provided on the substrate and arranged next to the light-emitting elements, and a first light-receiving color filter on the first light-receiving element, wherein the first light-receiving element may include a first transparent light-receiving electrode, a first light-absorbing layer on the first transparent light-receiving electrode, and an opposite electrode on the first light-absorbing layer, the first light-absorbing layer may include a material that has sensitivity to light of a first wavelength, light of a second wavelength, and light of a third wavelength, the first light-receiving color filter may be configured to transmit the light of the first wavelength, the light of the first wavelength may be one of green light, red light, and blue light, the light of the second wavelength may be another one of the green light, the red light, and the blue light, and the light of the third wavelength may be yet another one of the green light, the red light, and the blue light.

According to some embodiments, the first light-receiving element may not include a metal layer and a reflective electrode, on a lower surface of the first light-absorbing layer.

According to some embodiments, each of the light-emitting elements may include a stack of a pixel electrode and an emission layer on the pixel electrode, the pixel electrode may include a metal layer, and the metal layer may include a material different from that of the first transparent light-receiving electrode.

According to some embodiments, the opposite electrode may extend onto an upper surface of the emission layer, and a thickness of the first transparent light-receiving electrode may be different from a thickness of the pixel electrode.

According to some embodiments, the pixel electrode may further include a lower transparent electrode on a lower surface of the metal layer, and an upper transparent electrode on an upper surface of the metal layer.

According to some embodiments, the display apparatus may further include a second light-receiving element arranged next to the light-emitting elements, and a second light-receiving color filter on the second light-receiving element and configured to transmit the light of the second wavelength, wherein the second light-receiving element may include a second transparent light-receiving electrode and a second light-absorbing layer on the second transparent light-receiving electrode.

According to some embodiments, the second light-absorbing layer may include a material that has sensitivity to the light of the first wavelength, the light of the second wavelength, and the light of the third wavelength.

According to some embodiments, the second transparent light-receiving electrode may include a material same as that of the first transparent light-receiving electrode.

According to some embodiments, a thickness of the second transparent light-receiving electrode may be equal to a thickness of the first transparent light-receiving electrode.

According to some embodiments, the display apparatus may further include a third light-receiving element arranged next to the light-emitting elements, and a third light-receiving color filter on the third light-receiving element and configured to transmit the light of the third wavelength, wherein the third light-receiving element may include a third transparent light-receiving electrode and a third light-absorbing layer on the third transparent light-receiving electrode.

According to some embodiments, the display apparatus may further include a fourth light-receiving element arranged next to the light-emitting elements and including a fourth transparent light-receiving electrode and a fourth light-absorbing layer on the fourth transparent light-receiving electrode, and a fourth light-receiving color filter on the fourth light-receiving element, wherein the fourth light-absorbing layer may have sensitivity to the light of the first wavelength, the light of the second wavelength, the light of the third wavelength, and near-infrared rays, and the fourth light-receiving color filter may transmit the near-infrared rays.

According to some embodiments, the first light-absorbing layer may have sensitivity to the near-infrared rays.

According to one or more embodiments, a display apparatus may include a substrate, a plurality of light-emitting elements on the substrate, a first light-receiving element arranged next to the light-emitting elements, a second light-receiving element arranged next to the light-emitting elements, a first light-receiving color filter on the first light-receiving element, and a second light-receiving color filter on the second light-receiving element and configured to transmit light of a wavelength different from that of the first light-receiving color filter, wherein the first light-receiving element may include a first transparent light-receiving electrode and a first light-absorbing layer on the first transparent light-receiving electrode, the second light-receiving element may include a second transparent light-receiving electrode and a second light-absorbing layer on the second transparent light-receiving electrode, and the second light-absorbing layer may include a material same as that of the first light-absorbing layer.

According to some embodiments, the display apparatus may further include a planarizing insulating layer on the substrate, and a pixel-defining film on the first and second transparent light-receiving electrodes, wherein lower surfaces of the first and second transparent light-receiving electrodes may be in physical contact with the planarizing insulating layer, and upper surfaces of the first and second transparent light-receiving electrodes may be in physical contact with the pixel-defining film.

According to some embodiments, the substrate may have a first display region and a second display region, the light-emitting elements may be on the first display region and the second display region of the substrate, the first light-receiving element may be on the first display region of the substrate, and the second light-receiving element may be on the second display region of the substrate.

According to some embodiments, the first light-receiving element includes a plurality of first light-receiving elements, at least one of the plurality of first light-receiving elements may be on the first display region, and another one of the plurality of first light-receiving elements may be provided on the second display region.

According to some embodiments, the second light-receiving element may be apart from the first display region.

According to some embodiments, the display apparatus may further include a third light-receiving element arranged next to the light-emitting elements, and a third light-receiving color filter on the third light-receiving element and configured to transmit light of a wavelength different from that of each of the first light-receiving color filter and the second light-receiving color filter, wherein the substrate may include a third display region, and the third light-receiving element may be provided on the third display region of the substrate.

According to some embodiments, the third light-receiving element may include a third transparent light-receiving electrode and a third light-absorbing layer on the third transparent light-receiving electrode, and the third light-absorbing layer may include a material same as that of each of the first light-absorbing layer and the second light-absorbing layer.

According to some embodiments, the second light-receiving element may include a plurality of second light-receiving elements, at least one of the plurality of second light-receiving elements may be on the second display region of the substrate, another one of the plurality of second light-receiving elements may be provided on the third display region of the substrate, and the third light-receiving element may be apart from the first display region and the second display region of the substrate.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a portion of a display apparatus according to some embodiments;

FIG. 2 is an equivalent circuit diagram of a pixel according to some embodiments;

FIG. 3 is a schematic cross-sectional view of a display apparatus in a first display region of a substrate, according to some embodiments, and is a cross-section of the display apparatus of FIG. 1 taken along the line I-I′ of FIG. 1;

FIG. 4 is a diagram for explaining a fingerprint sensing function of a display apparatus in a first display region of a substrate, according to some embodiments;

FIG. 5 is a schematic cross-sectional view of a display apparatus in a second display region of a substrate, according to some embodiments, and is a cross-section of the display apparatus of FIG. 1 taken along the line II-II′ of FIG. 1;

FIG. 6 is a schematic cross-sectional view of a display apparatus in a third display region of a substrate, according to some embodiments, and is a cross-section of the display apparatus of FIG. 1 taken along the line III-III′ of FIG. 1; and

FIG. 7 is a schematic cross-sectional view of a display apparatus in a second display region of a substrate, according to some embodiments.

### DETAILED DESCRIPTION

Reference will now be made in more detail to aspects of some embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any suitable combination of a, b, and/or c.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, aspects of some embodiments will be described, in more detail, with reference to the accompanying drawings, and in the description with reference to the drawings, the same or corresponding components are indicated by the same reference numerals and redundant descriptions thereof are omitted.

In the following embodiments, it will be understood that although the terms “first,” “second,” etc. may be used herein to describe various components, these components should not be limited by these terms. These terms are only used to distinguish one component from another.

In the following embodiments, the expression of singularity in the present specification includes the expression of plurality unless clearly specified otherwise in context.

In the following embodiments, it will be further understood that the terms “comprises” and/or “comprising” used herein specify the presence of stated features or components, but do not preclude the presence or addition of one or more other features or components.

In the following embodiments, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being “connected to” another layer, area, or component, it can be directly or indirectly connected to the other layer, region, or component. That is, for example, intervening layers, regions, or components may be present. For example, in the specification, when a layer, region, or component is electrically connected to another layer, region, or component, the layers, regions, or components may not only be directly electrically connected, but may also be indirectly electrically connected via another layer, region, or component therebetween.

Throughout the specification, the same reference numerals may denote the same components.

Hereinafter, a display apparatus according to some embodiments is described.

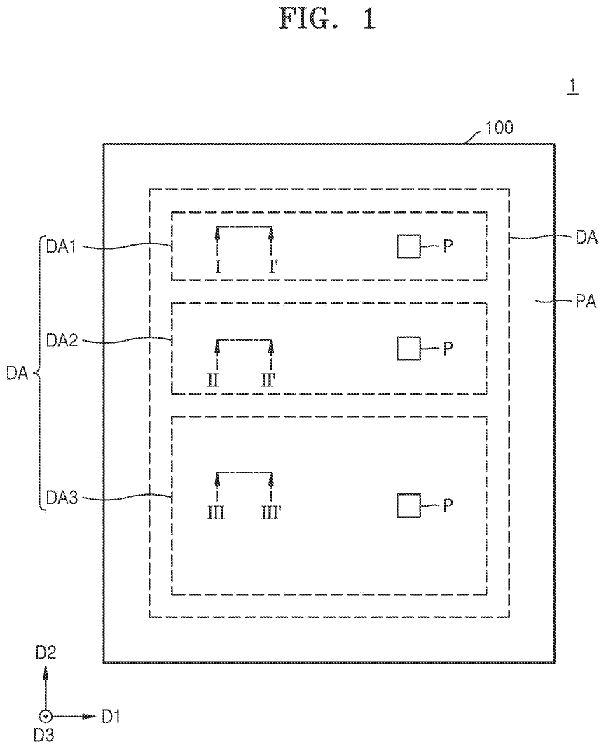

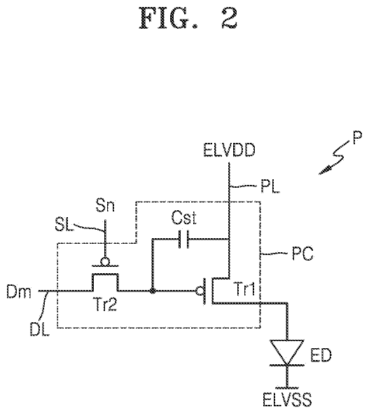

FIG. 1 is a schematic plan view of a portion of a display apparatus according to some embodiments. FIG. 2 is an equivalent circuit diagram of a pixel according to some embodiments.

Referring to FIGS. 1 and 2, a substrate 100 of a display apparatus 1 according to some embodiments may include a display region DA and a peripheral region PA. The peripheral region PA may be arranged outside the display region DA to surround the display region DA. The peripheral region PA may include various wires configured to transfer electrical signals to the display region DA, and a driving circuit unit. The display apparatus 1 may provide a certain image by using light emitted from a plurality of pixels P arranged in the display region DA.

The display region DA of the substrate 100 may include a first display region DA1, a second display region DA2, and a third display region DA3. The pixels P may be arranged in each of the first display region DA1, the second display region DA2, and the third display region DA3 of the substrate 100. Accordingly, the pixels P of the first display region DA1, the pixels P of the second display region DA2, and the pixels P of the third display region DA3 may each emit red light, green light, blue light, or white light.

Each of the pixels P may include a light-emitting element ED. The light-emitting element ED may emit, for example, red, green, or blue light, or red, green, blue, or white light. The light-emitting element ED may include an organic light-emitting diode (OLED) or an inorganic light-emitting diode. Each of the pixels P may be connected with a pixel circuit PC including first and second thin-film transistors Tr1 and Tr2 and a storage capacitor Cst, as shown in FIG. 2. The pixel circuit PC may be connected with a scan line SL, a data line DL crossing the scan line SL, and a driving voltage line PL.

Each of the pixels P may emit light by driving of the pixel circuit PC, and the display region DA provides a certain image via light emitted from the plurality of pixels P. The pixel P in the present specification may be defined as an emission region emitting one of red light, green light, blue light, or white light as described above.

The peripheral region PA is where the pixels P are not arranged, and may not provide an image. In the peripheral region PA, a printed circuit board including an embedded driving circuit unit, a power supply line, and a driving circuit unit, which are configured to drive the pixels P, or a terminal unit to which a driver IC is connected may be arranged.

In each of the pixels P, the light-emitting element ED is connected to the pixel circuit PC. The pixel circuit PC may include the first thin-film transistor Tr1, the second thin-film transistor Tr2, and the storage capacitor Cst, as shown in FIG. 2.

The second thin-film transistor Tr2 is a switching thin-film transistor and may be connected to the scan line SL and the data line DL. The second thin-film transistor Tr2 may be configured to transfer a data voltage input from the data line DL to the first thin-film transistor Tr1 according to a switching voltage input from the scan line SL.

The storage capacitor Cst may be connected to the second thin-film transistor Tr2 and the driving voltage line PL. The storage capacitor Cst may be configured to store a voltage corresponding to a difference between a voltage received from the second thin-film transistor Tr2 and a first power voltage ELVDD supplied to the driving voltage line PL.

The first thin-film transistor Tr1 is a driving thin-film transistor and may be connected to the driving voltage line PL and the storage capacitor Cst. The first thin-film transistor Tr1 may be configured to control a driving current flowing from the driving voltage line PL to the light-emitting element ED, according to a voltage value stored in the storage capacitor Cst. The light-emitting element ED may emit light having a certain luminance according to the driving current. An opposite electrode (for example, a cathode) of the light-emitting element ED may receive a second power voltage ELVSS.

FIG. 2 illustrates that the pixel circuit PC includes two thin-film transistors Tr1 and Tr2 and one storage capacitor Cst, but in some embodiments, the pixel circuit PC may include at least three transistors.

Referring back to FIG. 1, the first display region DA1 of the substrate 100 may be, for example, a fingerprint sensing region. The second display region DA2 of the substrate 100 may be, for example, a health case sensing region. The third display region DA3 of the substrate 100 may be an illuminance sensing region. A first direction D1 may parallel to an upper surface of the substrate 100. A second direction D2 may cross the first direction D1. A third direction D3 may cross the first direction D1 and the second direction D2. For example, the first direction D1 may be an x-axis direction, the second direction D2 may be a y-axis direction, and the third direction D3 may be a z-axis direction, but the disclosure is not limited thereto. The first display region DA1, the second display region DA2, and the third display region DA3 of the substrate 100 are shown as being arranged parallel to the second direction D2, but a planar arrangement of the first display region DA1, the second display region DA2, and the third display region DA3 of the substrate 100 is not limited to that shown in FIG. 1 and may be modified in various ways. Unlike shown, at least one of the first display region DA1, the second display region DA2, or the third display region DA3 of the substrate 100 may be omitted.

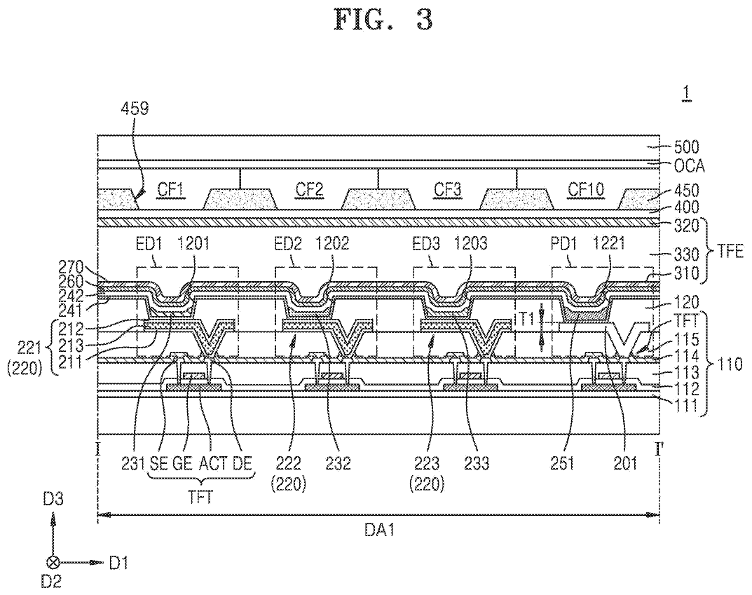

FIG. 3 is a schematic cross-sectional view of a display apparatus in a first display region of a substrate, according to some embodiments, and is a cross-section of the display apparatus of FIG. 1 taken along the line I-I′ of FIG. 1.

Referring to FIGS. 1 and 3, the display apparatus 1 may include the substrate 100, a pixel circuit layer 110, a pixel-defining film 120, a first light-emitting element ED1, a second light-emitting element ED2, a third light-emitting element ED3, a first light-receiving element PD1, an encapsulation layer TFE, a light-shielding pattern 450, a first color filter CF1, a second color filter CF2, a third color filter CF3, a first light-receiving color filter CF10, and a cover window 500.

The first light-emitting element ED1, the second light-emitting element ED2, the third light-emitting element ED3, and the first light-receiving element PD1 may be located on the first display region DA1 of the substrate 100. Each of the first light-emitting element ED1, the second light-emitting element ED2, and the third light-emitting element ED3 operates as described in the example of the light-emitting element ED in FIG. 2, and may have an electrical connection relationship as described in the example of the light-emitting element ED.

The substrate 100 may include a glass material or a polymer resin. For example, the substrate 100 may include a glass material containing silicon oxide (SiOₓ) as a main component, or may include a polymer resin such as polyethersulfone, polyarylate, polyetherimide, polyethylene naphthalate, polyethylene terephthalate, polyphenylene sulfide, polyimide, polycarbonate, cellulose triacetate, and/or cellulose acetate propionate.

The pixel circuit layer 110 may be located on the substrate 100. The pixel circuit layer 110 may include the pixel circuit PC (of FIG. 2) and insulating layers. For example, the pixel circuit layer 110 may include a thin-film transistor TFT, the storage capacitor Cst (of FIG. 2), a buffer layer 111, a gate insulating layer 112, an interlayer insulating film 113, a passivation layer 114, and a planarizing insulating layer 115.

The thin-film transistor TFT may include a semiconductor layer ACT, a gate electrode GE, a source electrode SE, and a drain electrode DE. The semiconductor layer ACT may include amorphous silicon, polycrystalline silicon, or an organic semiconductor material. The gate insulating layer 112 may be arranged between the semiconductor layer ACT and the gate electrode GE. The gate insulating layer 112 may ensure insulation between the semiconductor layer ACT and the gate electrode GE. The gate insulating layer 112 may include an inorganic material such as silicon oxide (SiOₓ), silicon nitride (SiNₓ), and/or silicon oxynitride (SiON). The gate insulating layer 112 may be formed via CVD or atomic layer deposition (ALD).

The interlayer insulating film 113 may be located on the gate electrode GE. The interlayer insulating film 113 may include an inorganic material such as silicon oxide (SiOₓ), silicon nitride (SiNₓ), and/or silicon oxynitride (SiON).

The source electrode SE and the drain electrode DE may be arranged in the interlayer insulating film 113. According to some embodiments, one of the source electrode SE and the drain electrode DE may be omitted and replaced with the conductive semiconductor layer ACT.

The gate electrode GE, the source electrode SE, and the drain electrode DE may be formed of various conductive materials. The gate electrode GE may include at least one of molybdenum (Mo), aluminum (Al), copper (Cu), or titanium (Ti). For example, the gate electrode GE may be a single layer of molybdenum (Mo). In contrast, the gate electrode GE may have a three-layer structure including a molybdenum layer, an aluminum layer, and a molybdenum layer. Each of the source electrode SE and the drain electrode DE may include at least one of copper (Cu), titanium (Ti), or aluminum (Al). Each of the source electrode SE and the drain electrode DE may be a single layer or a multilayer. For example, each of the source electrode SE and the drain electrode DE may be a three-layer structure including a titanium layer, an aluminum layer, and a titanium layer.

The passivation layer 114 may be provided on the interlayer insulating film 113 to cover the interlayer insulating film 113, the source electrode SE, and the drain electrode DE. The passivation layer 114 may prevent or reduce exposure of a metal wire to an etching environment during a process for manufacturing the display apparatus 1.

The buffer layer 111 may be arranged between the thin-film transistor TFT and the substrate 100. The buffer layer 111 may include an inorganic material such as silicon oxide (SiOₓ), silicon nitride (SiNₓ), and/or silicon oxynitride (SiON). The buffer layer 111 may increase the smoothness of the upper surface of the substrate 100 or may prevent or reduce instances of impurities or contaminants penetrating from the substrate 100 into the semiconductor layer ACT of the thin-film transistor TFT.

The planarizing insulating layer 115 may be located on the passivation layer 114. The planarizing insulating layer 115 may be formed of an organic material such as acryl, benzocyclobutene (BCB), or hexamethyldisiloxane (HMDSO). FIG. 3 illustrates that the planarizing insulating layer 115 is a single layer, but may be a multilayer.

Pixel electrodes 220 may be located on the planarizing insulating layer 115. Each of the pixel electrodes 220 may be connected with one of the corresponding source electrode SE and drain electrode DE through the planarizing insulating layer 115. Accordingly, each of the pixel electrodes 220 may be electrically connected with the corresponding thin-film transistor TFT. Each of the pixel electrodes 220 may include a lower transparent electrode 211, a metal layer 213, and an upper transparent electrode 212. The lower transparent electrode 211 may include a transparent conductive oxide. The transparent conductive oxide may include at least one selected from the group including indium tin oxide (ITO), indium zinc oxide (IZO), zinc oxide (ZnO), indium oxide (In₂O₃), indium gallium oxide (IGO), and aluminum zinc oxide (AZO). The metal layer 213 may be located on the lower transparent electrode 211. The metal layer 213 may include Ag or an Ag alloy. As another example, the metal layer 213 may include Mg, Al, Pt, Pd, Au, Ni, Nd, Ir, Cr, and a compound thereof. The upper transparent electrode 212 may be located on an upper surface of the metal layer 213. The upper transparent electrode 212 may include a transparent conductive oxide, and the transparent conductive oxide may include one of materials described in the example of the lower transparent electrode 211. As an example, each of the pixel electrodes 220 may include a stack of ITO/Ag/ITO.

The pixel electrodes 220 may include a first pixel electrode 221, a second pixel electrode 222, and a third pixel electrode 223. The first pixel electrode 221, the second pixel electrode 222, and the third pixel electrode 223 may include a same material and may have a substantially same structure. Each of the first pixel electrode 221, the second pixel electrode 222, and the third pixel electrode 223 may include the lower transparent electrode 211, the metal layer 213, and the upper transparent electrode 212 as described above. The first pixel electrode 221, the second pixel electrode 222, and the third pixel electrode 223 may be laterally apart from each other and may be electrically separated from each other. For example, the first pixel electrode 221, the second pixel electrode 222, and the third pixel electrode 223 may each independently operate, but the disclosure is not limited thereto. Each of the first pixel electrode 221, the second pixel electrode 222, and the third pixel electrode 223 may be an anode.

The first light-emitting element ED1 may include the first pixel electrode 221, a first emission layer 231, and an opposite electrode 260. The second light-emitting element ED2 may include the second pixel electrode 222, a second emission layer 232, and the opposite electrode 260. The third light-emitting element ED3 may include the third pixel electrode 223, a third emission layer 233, and the opposite electrode 260. The first light-emitting element ED1, the second light-emitting element ED2, and the third light-emitting element ED3 may be arranged in each pixel P (of FIG. 10). The first light-emitting element ED1, the second light-emitting element ED2, and the third light-emitting element ED3 may respectively emit light of a first wavelength, a second wavelength, and a third wavelength. The first wavelength, the second wavelength, and the third wavelength may be different from each other.

For example, the light of the first wavelength may be one of green light, red light, and blue light, the light of the second wavelength may be another one of the green light, the red light, and the blue light, and the light of the third wavelength may be yet another one of the green light, the red light, and the blue light. For example, the first wavelength may be about 495 nm to about 600 nm. The second wavelength may be about 600 nm to about 780 nm. The third wavelength may be about 380 nm to about 495 nm. Hereinafter, for convenience of explanation, a case where the first light-emitting element ED1 emits green light, the second light-emitting element ED2 emits red light, and the third light-emitting element ED3 emits blue light is described as an example, but the disclosure is not limited thereto.

The display apparatus 1 may further include the pixel-defining film 120. The pixel-defining film 120 may be located on the pixel electrodes 220. The pixel-defining film 120 may have a first light-emitting opening 1201, a second light-emitting opening 1202, a third light-emitting opening 1203, and a first light-receiving opening 1221. The first light-emitting opening 1201, the second light-emitting opening 1202, and the third light-emitting opening 1203 may respectively expose upper surfaces of the first pixel electrode 221, the second pixel electrode 222, and the third pixel electrode 223 through the pixel-defining film 120. Each of the upper surfaces of the first pixel electrode 221, the second pixel electrode 222, and the third pixel electrode 223 may correspond to an upper surface of the corresponding upper transparent electrode 212. The first light-emitting opening 1201, the second light-emitting opening 1202, and the third light-emitting opening 1203 may define emission regions of the pixel P (of FIG. 1).

The pixel-defining film 120 may cover an edge of each of the pixel electrodes 220 to increase a distance between an edge of the pixel electrode 220 and the opposite electrode 260, thereby preventing or reducing instances of arcs occurring at the edge of the pixel electrode 220.

The pixel-defining film 120 may include an organic insulating material such as polyimide, polyamide, an acrylic resin, benzocyclobutene, HMDSO, and a phenol resin. Alternatively, the pixel-defining film 120 may be formed of an inorganic insulating material. Alternatively, the pixel-defining film 120 may have a multilayer structure including an inorganic insulating material and an organic insulating material. The pixel-defining film 120 may be formed via a method such as spin coating.

According to some embodiments, the pixel-defining film 120 may be a black matrix. For example, the pixel-defining film 120 may include a light-blocking material and may be black. The light-blocking material may include resin or paste including carbon black, carbon nanotubes, or black dye, metal particles such as nickel, aluminum, molybdenum, and an alloy thereof, metal oxide particles (for example, chromium oxide), or metal nitride particles (for example, chromium nitride).

The first emission layer 231, the second emission layer 232, and the third emission layer 233 may be respectively located above the first pixel electrode 221, the second pixel electrode 222, and the third pixel electrode 223. The first emission layer 231, the second emission layer 232, and the third emission layer 233 may be laterally apart from each other. The first emission layer 231 may emit the light of the first wavelength. The second emission layer 232 may emit the light of the second wavelength different from the first wavelength. The third emission layer 233 may emit the light of the third wavelength. The third wavelength may be different from the first wavelength and the second wavelength. For example, the third emission layer 233 may emit blue light. When the first light-emitting element ED1 emits light, it may indicate that light is emitted from the first emission layer 231. Likewise, when the second light-emitting element ED2 emits light, it may indicate that the second emission layer 232 emits light, and when the third light-emitting element ED3 emits light, it may indicate that the third emission layer 233 emits light. The first emission layer 231, the second emission layer 232, and the third emission layer 233 may include different types of light-emitting materials. The light-emitting materials may be organic light-emitting materials, but is not limited thereto. For example, the first emission layer 231, the second emission layer 232, and the third emission layer 233 may include a fluorescent or phosphorescent material.

As another example, at least one of the first to third light-emitting elements ED1, ED2, or ED3 may be a white light-emitting element that emits white light. As another example, at least one of the first to third light-emitting elements may emit near-infrared rays.

Unlike shown, each of the first to third light-emitting elements may have a tandem structure. In this case, each of the first emission layer 231, the second emission layer 232, and the third emission layer 233 may include a stack of a plurality of sub-emission layers.

The display apparatus 1 may further include a first common layer 241. The first common layer 241 may be located on lower surfaces of the first to third emission layers 231, 232, and 233. For example, the first common layer 241 may be arranged between the first pixel electrode 221 and the first emission layer 231, between the second pixel electrode 222 and the second emission layer 232, and between the third pixel electrode 223 and the third emission layer 233. The first common layer 241 may extend between an upper surface of the pixel-defining film 120 and a lower surface of the opposite electrode 260, and may further cover inner walls of the first to third light-emitting openings 1201, 1202, and 1203. The first common layer 241 may include at least one of a hole transport layer (HTL) or a hole injection layer (HIL). The first common layer 241 may be a common layer integrally formed to entirely cover the substrate 100, for example, the display region DA (of FIG. 1) of the substrate 100. Each of the first light-emitting element ED1, the second light-emitting element ED2, and the third light-emitting element ED3 may further include a corresponding portion of the first common layer 241.

The opposite electrode 260 may be located above the first emission layer 231, the second emission layer 232, and the third emission layer 233. The opposite electrode 260 may further extend onto the inner walls of the first to third light-emitting openings 1201, 1202, and 1203 and the upper surface of the pixel-defining film 120. The opposite electrode 260 may be a common electrode. For example, the opposite electrode 260 may be a common layer integrally formed to entirely cover the substrate 100, for example, the display region DA (of FIG. 1) of the substrate 100. The opposite electrode 260 included in the first light-emitting element ED1, the opposite electrode 260 included in the second light-emitting element ED2, and the opposite electrode 260 included in the third light-emitting element ED3 may be connected to each other without boundaries. When the first light-emitting element ED1 includes the opposite electrode 260, it may indicate that the first light-emitting element ED1 includes a first portion of the opposite electrode 260. When the second light-emitting element ED2 includes the opposite electrode 260, it may indicate that the second light-emitting element ED2 includes a second portion of the opposite electrode 260. When the third light-emitting element ED3 includes the opposite electrode 260, it may indicate that the third light-emitting element ED3 includes a third portion of the opposite electrode 260.

The opposite electrode 260 may be a cathode which is an electron injection electrode. In this case, a metal, an alloy, an electrically conductive compound, or any combination thereof, each having a low work function, may be used as a material of the opposite electrode 260. The opposite electrode 260 may include a reflective electrode. The opposite electrode 260 may include, for example, lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The opposite electrode 260 may have a single-layer structure having a single layer or a multilayer structure having a plurality of layers.

The display apparatus 1 may further include a second common layer 242. The second common layer 242 may be located on upper surfaces of the first to third emission layers 231, 232, and 233. The second common layer 242 may be arranged between the first to third emission layers 231, 232, and 233 and the opposite electrode 260 and between the first common layer 241 and the opposite electrode 260. The second common layer 242 may include at least one of an electron transport layer (ETL) or an electron injection layer (EIL). The second common layer 242 may further include a buffer layer. Like the opposite electrode 260, the second common layer 242 may be a common layer integrally formed to entirely cover the substrate 100, for example, the display region DA (of FIG. 1) of the substrate 100.

The first light-receiving element PD1 may be provided on the first display region DA1 of the substrate 100, and may be arranged next to the first light-emitting element ED1, the second light-emitting element ED2, and the third light-emitting element ED3. The first light-receiving element PD1 may include a first transparent light-receiving electrode 201, a first light-absorbing layer 251, and the opposite electrode 260.

The first transparent light-receiving electrode 201 may be provided on the planarizing insulating layer 115 and laterally apart from the first to third pixel electrodes 221, 222, and 223. The first transparent light-receiving electrode 201 may be connected with one of the corresponding source electrode SE and drain electrode DE through the planarizing insulating layer 115. Accordingly, the first transparent light-receiving electrode 201 may be electrically connected with the corresponding thin-film transistor TFT. The first transparent light-receiving electrode 201 may be an anode of the first light-receiving element PD1. The first transparent light-receiving electrode 201 may be formed by a process different from a process for forming the first to third pixel electrodes 221, 222, and 223.

The first transparent light-receiving electrode 201 may have a structure different from that of each of the first pixel electrode 221, the second pixel electrode 222, and the third pixel electrode 223. Each of the first to third pixel electrodes 221, 222, and 223 may include a material different from that of the first transparent light-receiving electrode 201. For example, the metal layer 213 of each of the first to third pixel electrodes 221, 222, and 223 may include a material different from that of the first transparent light-receiving electrode 201. The first transparent light-receiving electrode 201 may include a transparent conductive oxide. The transparent conductive oxide may include at least one selected from the group including indium tin oxide (ITO), indium zinc oxide (IZO), zinc oxide (ZnO), indium oxide (In₂O₃), indium gallium oxide (IGO), and aluminum zinc oxide (AZO). The first transparent light-receiving electrode 201 may be a single transparent conductive oxide layer or a multilayer transparent conductive oxide layer. The first transparent light-receiving electrode 201 may have a first thickness T1, and the first thickness T1 may be different from the thicknesses of the first to third pixel electrodes 221, 222, and 223, but the disclosure is not limited thereto. The thickness of the first transparent light-receiving electrode 201 may be about 70 Å to about 1,000 Å.

The pixel-defining film 120 may cover an upper surface of the first transparent light-receiving electrode 201. The first light-receiving opening 1221 of the pixel-defining film 120 may expose at least a portion of the upper surface of the first transparent light-receiving electrode 201. The pixel-defining film 120 may cover an edge of the first transparent light-receiving electrode 201 to increase a distance between the edge of the first transparent light-receiving electrode 201 and the opposite electrode 260.

The first light-receiving element PD1 may not include a reflective electrode or a metal electrode as an anode. Accordingly, a lower surface of the first transparent light-receiving electrode 201 may be in physical contact with the planarizing insulating layer 115, and the upper surface of the first transparent light-receiving electrode 201 may be in physical contact with the pixel-defining film 120.

The first light-absorbing layer 251 may be located above the first transparent light-receiving electrode 201 and arranged in the first light-receiving opening 1221. The first light-absorbing layer 251 may include a material different from that of each of the first to third emission layers 231, 232, and 233, and may have a function different from that of each of the first to third emission layers 231, 232, and 233. The first light-absorbing layer 251 may sense light by including a photodiode such as a white photodiode. The first light-absorbing layer 251 may include a material that senses the light of the first wavelength, the second wavelength, and the third wavelength. The material included in the first light-absorbing layer 251 may further have sensitivity to light of a fourth wavelength.

For example, the first light-absorbing layer 251 may receive light from the outside to generate excitons and then separate the generated excitons into holes and electrons. When a (+) potential is applied to the first transparent light-receiving electrode 201 and a (−) potential is applied to the opposite electrode 260, holes separated in the first light-absorbing layer 251 may move to the opposite electrode 260, and electrons separated in the first light-absorbing layer 251 may move to the first transparent light-receiving electrode 201. Accordingly, a photocurrent may be formed in a direction from the first transparent light-receiving electrode 201 to the opposite electrode 260. When a bias is applied between the first transparent light-receiving electrode 201 and the opposite electrode 260, a dark current may flow through the first light-receiving element PD1. In addition, when light is incident on the first light-receiving element PD1, a photocurrent may flow through the first light-receiving element PD1. According to some embodiments, the first light-receiving element PD1 may detect the amount of light from a ratio of a photocurrent and a dark current.

The first light-absorbing layer 251 may include a p-type organic semiconductor material and an n-type organic semiconductor material. In this case, the p-type organic semiconductor material may act as an electron donor, and the n-type organic semiconductor material may act as an electron acceptor. For example, the p-type organic semiconductor material may include boron subphthalocyanine chloride (SubPc), copper(II) phthalocyanine (CuPc), tetraphenyldibenzoferiplanthene (DBP), or any combination thereof. The n-type organic semiconductor material may include C60 fullerene, C70 fullerene, or any combination thereof, but is not limited thereto.

The opposite electrode 260 may be further located above the first light-absorbing layer 251. The opposite electrode 260 may extend onto the upper surface of the pixel-defining film 120 from the first emission layer 231, the second emission layer 232, and the third emission layer 233, and may be provided on an upper surface of the first light-absorbing layer 251. The opposite electrode 260 above the first light-absorbing layer 251 may be integrally formed with the opposite electrode 260 above the first emission layer 231, the second emission layer 232, and the third emission layer 233. For example, the opposite electrode 260 included in the first light-receiving element PD1 may be connected with the opposite electrode 260 included in the first light-emitting element ED1, the opposite electrode 260 included in the second light-emitting element ED2, and the opposite electrode 260 included in the third light-emitting element ED3 without boundaries. When the first light-receiving element PD1 includes the opposite electrode 260, it may indicate that the first light-receiving element PD1 includes a fourth portion of the opposite electrode 260.

The first common layer 241 may extend onto an inner wall of the first light-receiving opening 1221 and may be further provided between the first transparent light-receiving electrode 201 and the first light-absorbing layer 251. Accordingly, the first light-receiving element PD1 may further include a corresponding portion of the first common layer 241. The corresponding portion of the first common layer 241 may be provided between the first transparent light-receiving electrode 201 and the first light-absorbing layer 251.

The second common layer 242 may further extend onto the upper surface of the first light-absorbing layer 251. The second common layer 242 may be arranged between the first light-absorbing layer 251 and the opposite electrode 260. Accordingly, the first light-receiving element PD1 may further include a corresponding portion of the second common layer 242. The corresponding portion of the second common layer 242 may be provided between the first light-absorbing layer 251 and the opposite electrode 260.

The display apparatus 1 may further include a capping layer 270. The capping layer 270 may be vertically apart from the first emission layer 231, the second emission layer 232, the third emission layer 233, and the first light-absorbing layer 251, and may cover an upper surface of the opposite electrode 260. A vertical direction in the present specification may refer to the third direction D3 or a direction opposite to the third direction D3. The capping layer 270 may include an organic material and may protect the opposite electrode 260. For example, the capping layer 270 may further serve to improve the external luminescence efficiency of the first light-emitting element ED1, the second light-emitting element ED2, and the third light-emitting element ED3 according to the principle of constructive interference. In this case, the capping layer 270 may have a refractive index of about 1.7 to about 2.1. In addition, the capping layer 270 may serve to facilitate smooth movement of holes by lowering a energy barrier of the holes moving toward a hole transport layer and an anode.

According to some embodiments, each of the first to third light-emitting elements ED1, ED2, and ED3 may have a resonant structure. For example, the metal layer 213 of the pixel electrode 220 may be a reflective electrode or a semipermeable electrode. A resonant structure may be formed between the metal layer 213 of the pixel electrode 220 and the opposite electrode 260. For example, a distance between the metal layer 213 and the opposite electrode 260 may satisfy a constructive interference condition, and while light emitted from the first emission layer 231 is repeatedly reflected by the metal layer 213 and the opposite electrode 260, the full width at half maximum may decrease and the intensity may be amplified. Due to the resonant structure, the light extraction efficiency of the first light-emitting element ED1 may be improved. The resonant structure may be equally applied to the second light-emitting element ED2 and the third light-emitting element ED3.

When the first light-receiving element PD1 has a resonant structure as described in the example of the first light-emitting element ED1, the first light-receiving element PD1 may absorb and sense only light of a specific wavelength. The first light-receiving element PD1 may exhibit relatively low sensing sensitivity and sensing reliability.

According to some embodiments, the first light-receiving element PD1 may include the first transparent light-receiving electrode 201, but may not include a reflective electrode, a metal electrode, and a metal layer on a lower surface of the first light-absorbing layer 251. Accordingly, light incident on the first light-receiving element PD1 may not travel between the first transparent light-receiving electrode 201 and the opposite electrode 260, and may pass through the first transparent light-receiving electrode 201 and be emitted to the outside. Accordingly, the first light-receiving element PD1 may have a non-resonant structure, and the non-resonant structure may be formed between the first transparent light-receiving electrode 201 and the opposite electrode 260. Accordingly, the first light-receiving element PD1 may absorb light in a relatively wide wavelength band, and the light detection performance of the first light-receiving element PD1 may be improved. For example, the first light-receiving element PD1 may have sensitivity to the light of the fourth wavelength as well as the light of the first wavelength, the second wavelength, and the third wavelength. The fourth wavelength may be about 750 nm to about 1,000 nm. The fourth wavelength may be a near-infrared ray. In addition, the sensing sensitivity, sensing reliability, and external quantum efficiency (EQE) characteristics of the first light-receiving element PD1 may be improved.

The encapsulation layer TFE may be located on the first light-emitting element ED1, the second light-emitting element ED2, the third light-emitting element ED3, and the first light-receiving element PD1. The encapsulation layer TFE may include a first inorganic encapsulation layer 310, a second inorganic encapsulation layer 320, and an organic encapsulation layer 330. The first inorganic encapsulation layer 310 may be provided on the capping layer 270. The first inorganic encapsulation layer 310 may include an inorganic insulating material. The inorganic insulating material may include aluminum oxide, titanium oxide, tantalum oxide, hafnium oxide, zinc oxide, silicon oxide, silicon nitride, or/and silicon oxynitride. The first inorganic encapsulation layer 310 may be formed via chemical vapor deposition. The first inorganic encapsulation layer 310 may be transparent.

The organic encapsulation layer 330 may be located on an upper surface of the first inorganic encapsulation layer 310 to cover the upper surface of the first inorganic encapsulation layer 310. The organic encapsulation layer 330 may include polymer. The polymer may include an acrylic resin, an epoxy-based resin, polyimide, and polyethylene. For example, the organic encapsulation layer 330 may include an acrylic resin such as polymethyl methacrylate and/or polyacrylic acid. The organic encapsulation layer 330 may be formed by curing a monomer or applying a polymer. The organic encapsulation layer 330 may cover irregularities of the first light-emitting element ED1, the second light-emitting element ED2, the third light-emitting element ED3, and the first light-receiving element PD1, and accordingly, an upper surface of the organic encapsulation layer 330 may be flatter than the upper surface of the first inorganic encapsulation layer 310. The organic encapsulation layer 330 may be transparent.

The second inorganic encapsulation layer 320 may be provided on the upper surface of the organic encapsulation layer 330. The second inorganic encapsulation layer 320 may include an inorganic insulating material described in the example of the first inorganic encapsulation layer 310. The second inorganic encapsulation layer 320 may be formed via chemical vapor deposition. The second inorganic encapsulation layer 320 may be transparent.

The display apparatus 1 may further include a touch sensor layer 400. The touch sensor layer 400 may be located on the encapsulation layer TFE. The touch sensor layer 400 may sense a user's touch input. The touch sensor layer 400 may detect a user's touch input by using a resistive method or a capacitive method. Unlike shown, the touch sensor layer 400 may be omitted. The touch sensor layer 400 may include a stack of insulating layers and conductive layers. The conductive layers may be arranged between the insulating layers and may function as touch electrodes.

The light-shielding pattern 450 may be located on the touch sensor layer 400. The light-shielding pattern 450 may absorb or reflect light. The light-shielding pattern 450 may have upper openings 459. The upper openings 459 may expose an upper surface of the touch sensor layer 400 through the light-shielding pattern 450. The upper openings 459 may vertically overlap corresponding ones of the first to third light-emitting openings 1201, 1202, and 1203 and the first light-receiving opening 1221. The light-shielding pattern 450 may have a mesh shape in plan view, by including the upper openings 459. The light-shielding pattern 450 may include an insulating material (for example, an organic insulating material) and a light-shielding material. The light-shielding material may include black pigment or black dye. The light-shielding pattern 450 may be, for example, a black matrix. The light-shielding pattern 450 may be arranged to correspond to a non-emission region, and may prevent or reduce color mixing via light leakage between the pixels P (of FIG. 1). The non-emission region may not vertically overlap the first to third light-emitting openings 1201, 1202, and 1203 and the first light-receiving opening 1221. The light-shielding pattern 450 may vertically overlap the pixel-defining film 120, and the pixel-defining film 120 may include a light-blocking material as described above. In this case, a light-shielding function of the pixel-defining film 120 and the light-shielding pattern 450 may be maximized.

The first color filter CF1, the second color filter CF2, and the third color filter CF3 may be provided on the first display region DA1 of the substrate 100. The first color filter CF1, the second color filter CF2, and the third color filter CF3 may be located on the upper surface of the touch sensor layer 400 and arranged in the upper openings 459 of the light-shielding pattern 450. Each of the first color filter CF1, the second color filter CF2, and the third color filter CF3 transmits only light having a specific wavelength and may filter out light of other wavelengths. The first to third color filters CF1, CF2, and CF3 may be arranged in consideration of colors of light emitted from the pixels P of a display panel. For example, the arrangement of the first to third color filters CF1, CF2, and CF3 may be determined according to colors of light emitted from the first to third light-emitting elements ED1, ED2, and ED3.

The first color filter CF1 may be located above the first light-emitting element ED1. The first color filter CF1 may vertically overlap the first light-emitting opening 1201. The first color filter CF1 may transmit the light of the first wavelength. Accordingly, the first light-emitting element ED1 may emit the light of the first wavelength, and the first color filter CF1 may transmit the light of the first wavelength emitted from the first light-emitting element ED1. For example, the first color filter CF1 may be a green color filter.

The second color filter CF2 may be located above the second light-emitting element ED2. The second color filter CF2 may vertically overlap the second light-emitting opening 1202. The second light-emitting element ED2 may emit the light of the second wavelength. The second color filter CF2 may transmit the light of the second wavelength. For example, the second color filter CF2 may be a red color filter.

The third color filter CF3 may be located above the third light-emitting element ED3. The third color filter CF3 may vertically overlap the third light-emitting opening 1203. The third light-emitting element ED3 may emit the light of the third wavelength. The third color filter CF3 may transmit the light of the third wavelength. For example, the third color filter CF3 may be a blue color filter.

The first light-receiving color filter CF10 may be located above the first light-receiving element PD1. The first light-receiving color filter CF10 may vertically overlap the first light-receiving opening 1221. The first light-receiving color filter CF10 may be provided on the upper surface of the touch sensor layer 400 and may be arranged in one of the upper openings 459 of the light-shielding pattern 450. The first light-receiving color filter CF10 may be arranged next to the first color filter CF1, the second color filter CF2, and the third color filter CF3. The first light-receiving color filter CF10 may include an organic material, but is not limited thereto.

The first light-receiving color filter CF10 may transmit the light of the first wavelength. For example, the first light-receiving color filter CF10 may be a green color filter. Among external light, the light of the first wavelength may pass through the first light-receiving color filter CF10 and may be incident on the first light-receiving element PD1. Accordingly, the first light-receiving element PD1 may detect the light of the first wavelength.

The wavelength of light transmitted by the first light-receiving color filter CF10 may be modified in various ways. For example, the first light-receiving color filter CF10 may transmit the light of the second wavelength. In this case, the light of the second wavelength may be incident on the first light-receiving color filter CF10, and the first light-receiving color filter CF10 may detect the light of the second wavelength. As another example, the first light-receiving color filter CF10 may transmit the light of the third wavelength, and the first light-receiving color filter CF10 may detect the light of the third wavelength.

The cover window 500 may be located above the first to third color filters CF1, CF2, and CF3 and the first light-receiving color filter CF10. The cover window 500 may be transparent. The cover window 500 may include at least one of glass, sapphire, or plastic. The cover window 500 may be, for example, ultra-thin glass (UTG) or colorless polyimide (CPI).

The display apparatus 1 may further include a window adhesive layer OCA. The window adhesive layer OCA may be arranged between the first to third color filters CF1, CF2, and CF3 and the cover window 500 and between the first light-receiving color filter CF10 and the cover window 500. The cover window 500 may be attached to the first to third color filters CF1, CF2, and CF3 and the first light-receiving color filter CF10 via the window adhesive layer OCA. The window adhesive layer OCA may include an optically clear adhesive. The optically clear adhesive may include an organic material such as polymer.

FIG. 3 illustrates that the first light-emitting element ED1, the second light-emitting element ED2, the third light-emitting element ED3, and the first light-receiving element PD1 are arranged in the first direction D1, but this is only an example, and the arrangement of the first light-emitting element ED1, the second light-emitting element ED2, the third light-emitting element ED3, and the first light-receiving element PD1 may be modified in various ways.

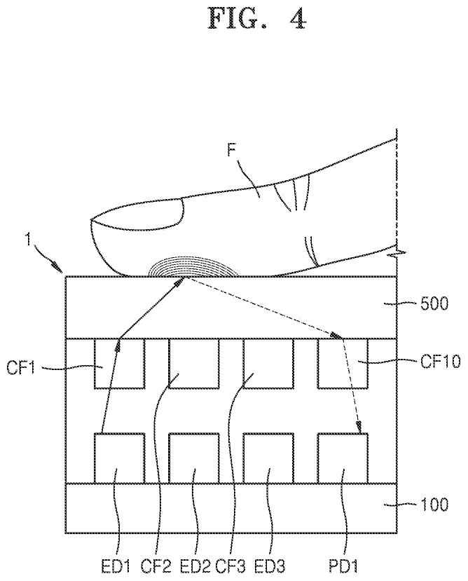

FIG. 4 is a schematic view of a display apparatus in a first display region of a substrate, according to some embodiments, and is a diagram for explaining a fingerprint sensing function of the display apparatus. Hereinafter, FIG. 4 is described with reference to FIG. 3, and redundant descriptions are omitted.

Referring to FIG. 4, the display apparatus 1 may include the substrate 100, the first light-emitting element ED1, the second light-emitting element ED2, the third light-emitting element ED3, the first light-receiving element PD1, the first color filter CF1, the second color filter CF2, the third color filter CF3, the first light-receiving color filter CF10, and the cover window 500. According to some embodiments, the display apparatus 1 may further include components as described in connection with FIG. 3.

The first display region DA1 of the substrate 100 may be, for example, a fingerprint sensing region. When a finger F of a user is in contact with the cover window 500, the display apparatus 1 may sense a fingerprint. For fingerprint sensing, it may be required to sense the light of the first wavelength reflected by the fingerprint. According to some embodiments, the light of the first wavelength emitted from the first light-emitting element ED1 may be reflected by the user's fingerprint. The reflected light of the first wavelength may be incident on the first light-receiving element PD1 via the first light-receiving color filter CF10. The first light-receiving element PD1 may detect the light of the first wavelength. Fingerprint Information of the finger F of the user may be obtained from a result of detection.

The light of the second and third wavelengths may have difficulty passing through the first light-receiving color filter CF10. Accordingly, the light of the second and third wavelengths may not be incident on the first light-receiving element PD1. Accordingly, noise light may be removed. According to some embodiments, the wavelength of light incident on the first light-receiving element PD1 may be controlled by selecting the type of the first light-receiving color filter CF10. Light of a target wavelength (for example, the light of the first wavelength) may be selectively incident on the first light-receiving element PD1 by the first light-receiving color filter CF10.

According to some embodiments, the display apparatus 1 may implement an image by using light emitted from the first to third light-emitting elements ED1, ED2, and ED3, and may obtain a user's fingerprint information by using the first light-emitting element ED1 and the first light-receiving element PD1.

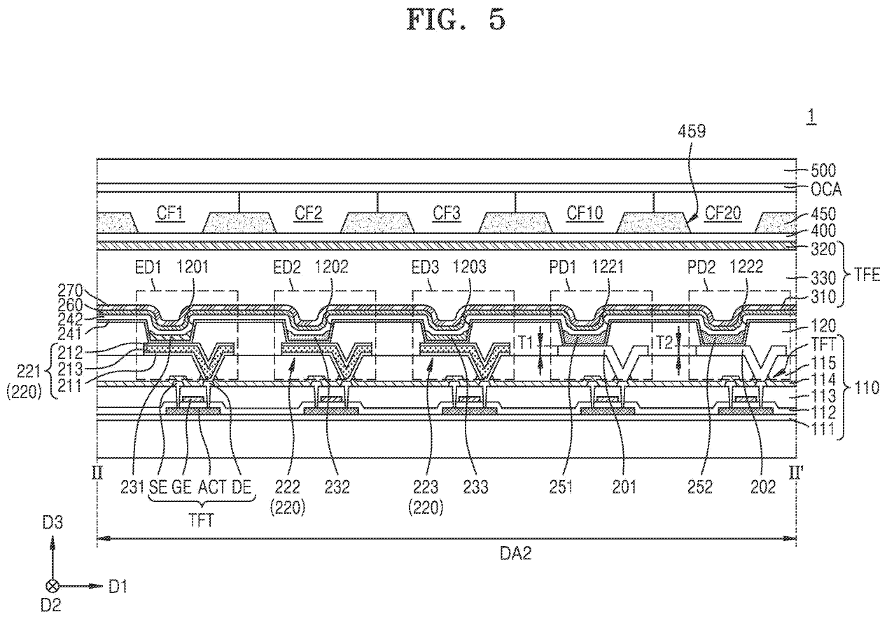

FIG. 5 is a schematic cross-sectional view of a display apparatus in a second display region of a substrate, according to some embodiments, and is a cross-section of the display apparatus of FIG. 1 taken along the line II-II′ of FIG. 1. Hereinafter, redundant descriptions are omitted.

Referring to FIG. 5, the display apparatus 1 may include the substrate 100, the pixel-defining film 120, the first light-emitting element ED1, the second light-emitting element ED2, the third light-emitting element ED3, the first light-receiving element PD1, a second light-receiving element PD2, the first color filter CF1, the second color filter CF2, the third color filter CF3, the first light-receiving color filter CF10, and a second light-receiving color filter CF20.

The first to third light-emitting elements ED1, ED2, and ED3, the first light-receiving element PD1, the first to third color filters CF1, CF2, and CF3, and the first light-receiving color filter CF10 may be located on the second display region DA2 of the substrate 100. The arrangement of the first to third light-emitting elements ED1, ED2, and ED3, the first to third color filters CF1, CF2, and CF3, the first light-receiving element PD1, and the first light-receiving color filter CF10 in the second display region DA2 of the substrate 100 may be substantially the same as described in the examples of the arrangement in the first display region DA1 of the substrate 100.

The second light-receiving element PD2 may be located on the second display region DA2 of the substrate 100, and may be arranged next to the first to third light-emitting elements ED1, ED2, and ED3 and the first light-receiving element PD1. The second light-receiving element PD2 may have a structure substantially identical to that of the first light-receiving element PD1, and may be manufactured via a single process with the first light-receiving element PD1. Accordingly, a process for manufacturing the first and second light-receiving elements PD1 and PD2 may be simplified.

The second light-receiving element PD2 may include a second transparent light-receiving electrode 202, a second light-absorbing layer 252, and the opposite electrode 260. The second transparent light-receiving electrode 202 may be provided on the planarizing insulating layer 115 and electrically connected with the corresponding thin-film transistor TFT. A lower surface of the second transparent light-receiving electrode 202 may be in physical contact with the planarizing insulating layer 115. The second transparent light-receiving electrode 202 may be laterally apart from the first to third pixel electrodes 221, 222, and 223 and the first transparent light-receiving electrode 201. The second transparent light-receiving electrode 202 may have a structure identical to that of the first transparent light-receiving electrode 201 and may include a material same as that of the first transparent light-receiving electrode 201. For example, the second transparent light-receiving electrode 202 may include a transparent conductive oxide. When the first transparent light-receiving electrode 201 is a single transparent conductive oxide layer, the second transparent light-receiving electrode 202 may also be a single transparent conductive oxide layer. When the first transparent light-receiving electrode 201 includes a multilayer of transparent conductive oxide layers, the second transparent light-receiving electrode 202 may also include a multilayer of transparent conductive oxide layers. A second thickness T2 of the second transparent light-receiving electrode 202 may be substantially equal to the first thickness T1. The second thickness T2 may be about 70 Å to 1,000 Å. The second transparent light-receiving electrode 202 may be formed via a single process with the first transparent light-receiving electrode 201.

The second transparent light-receiving electrode 202 may have a structure different from that of each of the first to third pixel electrodes 221, 222, and 223. Each of the first to third pixel electrodes 221, 222, and 223 may include a material different from that of the second transparent light-receiving electrode 202. The metal layer 213 of each of the first to third pixel electrodes 221, 222, and 223 may include a material different from that of the second transparent light-receiving electrode 202.

The pixel-defining film 120 may have a second light-receiving opening 1222. The second light-receiving opening 1222 may expose at least a portion of an upper surface of the second transparent light-receiving electrode 202. The pixel-defining film 120 may cover an edge of the second transparent light-receiving electrode 202. The upper surface of the second transparent light-receiving electrode 202 may be in physical contact with the pixel-defining film 120.

The second light-absorbing layer 252 may be located above the second transparent light-receiving electrode 202 and arranged in the second light-receiving opening 1222. The second light-absorbing layer 252 may include a material same as that of the first light-absorbing layer 251 and may have a structure identical to that of the first light-absorbing layer 251. The thickness of the second light-absorbing layer 252 may be substantially equal to the thickness of the first light-absorbing layer 251. The second light-absorbing layer 252 may be formed via a single process with the first light-absorbing layer 251. The second light-absorbing layer 252 may sense light by including a photodiode. For example, the second light-absorbing layer 252 may include a material that senses the light of the first wavelength, the second wavelength, and the third wavelength. The second light-absorbing layer 252 may further sense the light of the fourth wavelength.

According to some embodiments, the second light-receiving element PD2 may include the second transparent light-receiving electrode 202 and may not include a reflective electrode, a metal electrode, and a metal layer on a lower surface of the second light-absorbing layer 252. The second light-receiving element PD2 may have a non-resonant structure as described in the example of the first light-receiving element PD1. Accordingly, the second light-receiving element PD2 may absorb light in a relatively wide wavelength band. The light detection performance, sensing sensitivity, sensing reliability, and external quantum efficiency (EQE) characteristics of the second light-receiving element PD2 may be improved.

The opposite electrode 260 may extend onto the second light-absorbing layer 252. The opposite electrode 260 above the second light-absorbing layer 252 may be integrally formed with the opposite electrode 260 above the first to third emission layers 231, 232, and 233 and the opposite electrode 260 above the first light-absorbing layer 251. For example, the opposite electrode 260 included in the second light-receiving element PD2 may be connected with the opposite electrode 260 included in the first light-emitting element ED1, the opposite electrode 260 included in the second light-emitting element ED2, and the opposite electrode 260 included in the third light-emitting element ED3 without boundaries. When the second light-receiving element PD2 includes the opposite electrode 260, it may indicate that the second light-receiving element PD2 includes a fifth portion of the opposite electrode 260.

The first common layer 241 may extend onto an inner wall of the second light-receiving opening 1222 and may be further provided between the first transparent light-receiving electrode 201 and the second light-absorbing layer 252. Accordingly, the second light-receiving element PD2 may further include a corresponding portion of the second common layer 242. The corresponding portion of the second common layer 242 may be provided between the second transparent light-receiving electrode 202 and the second light-absorbing layer 252.

The second common layer 242 may further extend onto an upper surface of the second light-absorbing layer 252. Accordingly, the second light-receiving element PD2 may further include a corresponding portion of the second common layer 242. The corresponding portion of the second common layer 242 may be provided between the second light-absorbing layer 252 and the opposite electrode 260. The capping layer 270 may be vertically apart from the second light-absorbing layer 252 and may cover the upper surface of the opposite electrode 260.

The second light-receiving color filter CF20 may be located above the second light-receiving element PD2. The second light-receiving color filter CF20 may vertically overlap the second light-receiving opening 1222. The second light-receiving color filter CF20 may transmit the light of the second wavelength. The second light-receiving color filter CF20 may not transmit the light of the first and third wavelengths. For example, the second light-receiving color filter CF20 may be a red color filter. Accordingly, among external light, the light of the second wavelength may pass through the second light-receiving color filter CF20 and be incident on the second light-receiving element PD2. Accordingly, the second light-receiving element PD2 may detect the light of the second wavelength.

The second light-receiving color filter CF20 may be arranged next to the first color filter CF1, the second color filter CF2, the third color filter CF3, and the first light-receiving color filter CF10. The second light-receiving color filter CF20 may include an organic material, but is not limited thereto. The second display region DA2 of the substrate 100 may be, for example, a health case sensing region. In order to sense information about a user's health, it may be required to sense the light of the first wavelength and the light of the second wavelength. According to some embodiments, because the first light-receiving color filter CF10 and the second light-receiving color filter CF20 are provided, the light of the first wavelength may be selectively incident on the first light-receiving element PD1, and the light of the second wavelength may be selectively incident on the second light-receiving element PD2.

According to some embodiments, the first light-receiving element PD1 and the second light-receiving element PD2 are formed via a single process, and the wavelength of light incident on the first light-receiving element PD1 and the second light-receiving element PD2 may be controlled according to the types and arrangement of the first light-receiving color filter CF10 and the second light-receiving color filter CF20. Accordingly, manufacturing of the display apparatus 1 may be simplified.

FIG. 5 illustrates that the first light-emitting element ED1, the second light-emitting element ED2, the third light-emitting element ED3, the first light-receiving element PD1, and the second light-receiving element PD2 are arranged in the first direction D1, but this is only an example, and the arrangement of the first to third light-emitting elements ED1, ED2, and ED3, the first light-receiving element PD1, and the second light-receiving element PD2 may be modified in various ways.

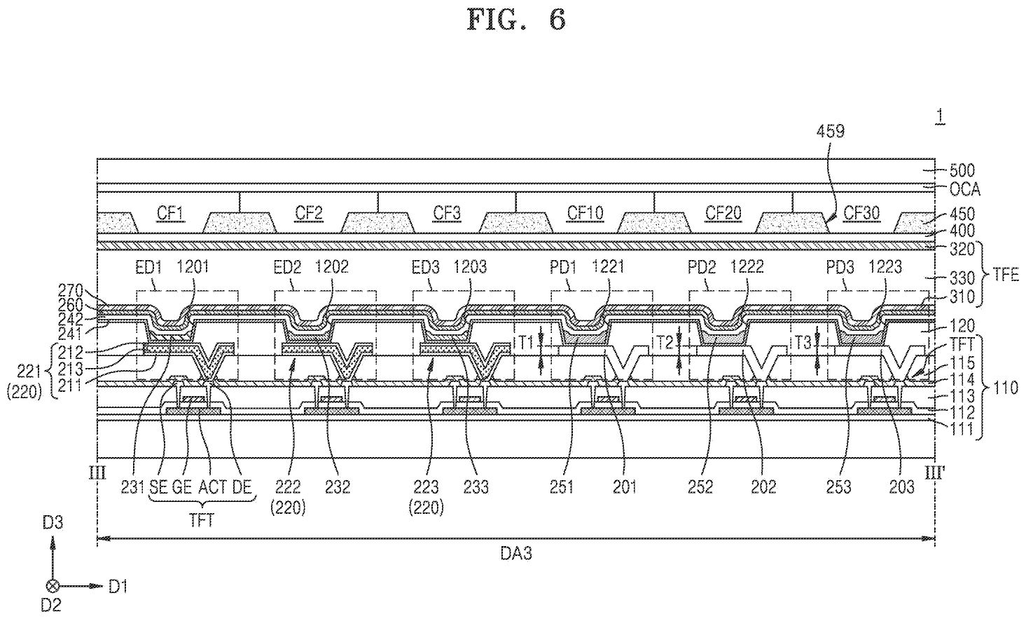

FIG. 6 is a schematic cross-sectional view of a display apparatus in a third display region of a substrate, according to some embodiments, and is a cross-section of the display apparatus of FIG. 1 taken along line III-III′ of FIG. 1. Hereinafter, redundant descriptions are omitted.

Referring to FIG. 6, the display apparatus 1 may include the substrate 100, the pixel-defining film 120, the first to third light-emitting elements ED1, ED2, and ED3, the first light-receiving element PD1, the second light-receiving element PD2, a third light-receiving element PD3, the first to third color filters CF1, CF2, and CF3, the first light-receiving color filter CF10, the second light-receiving color filter CF20, and a third light-receiving color filter CF30.

The first to third light-emitting elements ED1, ED2, and ED3, the first and second light-receiving elements PD1 and PD2, the first to third color filters CF1, CF2, and CF3, and the first and second light-receiving color filters CF10 and CF20 may be located on the third display region DA3 of the substrate 100. The arrangement of the first to third light-emitting elements ED1, ED2, and ED3, the first to third color filters CF1, CF2, and CF3, the first and second light-receiving elements PD1 and PD2, and the first and second light-receiving color filters CF10 and CF20 in the third display region DA3 of the substrate 100 is the same as described in the examples of FIGS. 3 and 4.

The third light-receiving element PD3 may be provided on the third display region DA3 of the substrate 100, and may be arranged next to the first to third light-emitting elements ED1, ED2, and ED3 and the first and second light-receiving elements PD1 and PD2. The third light-receiving element PD3 may be formed via a single process with the first light-receiving element PD1 and the second light-receiving element PD2. Accordingly, manufacturing of the display apparatus 1 may be simplified.

The third light-receiving element PD3 may include a third transparent light-receiving electrode 203, a third light-absorbing layer 253, and the opposite electrode 260. The third transparent light-receiving electrode 203 may be provided on the planarizing insulating layer 115 and laterally apart from the first to third pixel electrodes 221, 222, and 223, the first transparent light-receiving electrode 201, and the second transparent light-receiving electrode 202. The third transparent light-receiving electrode 203 may be connected with one of the corresponding source electrode SE and drain electrode DE through the planarizing insulating layer 115. The third transparent light-receiving electrode 203 may have a structure identical to that of each of the first and second transparent light-receiving electrodes 201 and 202, and may include a material same as that of each of the first and second transparent light-receiving electrodes 201 and 202. A third thickness T3 of the third transparent light-receiving electrode 203 may be substantially equal to the first thickness T1 and the second thickness T2. The third thickness T3 may be about 70 Å to about 1,000 Å. The third transparent light-receiving electrode 203 may be formed via a single process with the first transparent light-receiving electrode 201 and the second transparent light-receiving electrode 202. Each of the first to third pixel electrodes 221, 222, and 223 may include a material different from that of the third transparent light-receiving electrode 203.

The pixel-defining film 120 may further have a third light-receiving opening 1223. The third light-receiving opening 1223 may expose at least a portion of an upper surface of the third transparent light-receiving electrode 203. The pixel-defining film 120 may cover an edge of the third transparent light-receiving electrode 203.

The third light-absorbing layer 253 may be located above the third transparent light-receiving electrode 203 and arranged in the third light-receiving opening 1223. The third light-absorbing layer 253 may include a material same as that of each of the first light-absorbing layer 251 and the second light-absorbing layer 252. The third light-absorbing layer 253 may be formed via a single process with the first light-absorbing layer 251 and the second light-absorbing layer 252. The third light-absorbing layer 253 may sense light by including a photodiode such as a white photodiode. The third light-absorbing layer 253 may include a material that senses the light of the first wavelength, the second wavelength, and the third wavelength. The material of the third light-absorbing layer 253 may further sense the light of the fourth wavelength.

The opposite electrode 260 may extend onto the third light-absorbing layer 253. The opposite electrode 260 above the third light-absorbing layer 253 may be integrally formed with the opposite electrode 260 above the first to third emission layers 231, 232, and 233. For example, the opposite electrode 260 included in the third light-receiving element PD3 may be connected with the opposite electrode 260 included in the first light-emitting element ED1, the opposite electrode 260 included in the second light-emitting element ED2, and the opposite electrode 260 included in the third light-emitting element ED3 without boundaries. When the third light-receiving element PD3 includes the opposite electrode 260, it may indicate that the third light-receiving element PD3 includes a sixth portion of the opposite electrode 260.

The first common layer 241 may extend onto an inner wall of the third light-receiving opening 1223 and may be further provided between the first transparent light-receiving electrode 201 and the third light-absorbing layer 253. Accordingly, the third light-receiving element PD3 may further include a corresponding portion of the first common layer 241. The corresponding portion of the first common layer 241 may be provided between the third transparent light-receiving electrode 203 and the third light-absorbing layer 253.

The second common layer 242 may further extend onto an upper surface of the third light-absorbing layer 253. Accordingly, the third light-receiving element PD3 may further include a corresponding portion of the second common layer 242. The corresponding portion of the second common layer 242 may be provided between the third light-absorbing layer 253 and the opposite electrode 260.

The capping layer 270 may be vertically apart from the third light-absorbing layer 253 and may cover the upper surface of the opposite electrode 260.

According to some embodiments, the third light-receiving element PD3 may include the third transparent light-receiving electrode 203, but may not include a reflective electrode, a metal electrode, and a metal layer on a lower surface of the third light-absorbing layer 253. Accordingly, the third light-receiving element PD3 may have a non-resonant structure as described in the example of the first light-receiving element PD1. The third light-receiving element PD3 may absorb light in a relatively wide wavelength band. For example, the third light-receiving element PD3 may have sensitivity to the light of the fourth wavelength as well as the light of the first wavelength, the second wavelength, and the third wavelength. The light detection performance, sensing sensitivity, sensing reliability, and external quantum efficiency (EQE) characteristics of the third light-receiving element PD3 may be improved.

The third light-receiving color filter CF30 may be located above the third light-receiving element PD3 and may vertically overlap the third light-receiving opening 1223. The third light-receiving color filter CF30 may transmit the light of the third wavelength. For example, the third light-receiving color filter CF30 may be a blue color filter. Accordingly, among external light, the light of the third wavelength may pass through the third light-receiving color filter CF30 and be incident on the third light-receiving element PD3. Accordingly, the third light-receiving element PD3 may detect the light of the third wavelength. The third light-receiving color filter CF30 may be arranged next to the first color filter CF1, the second color filter CF2, and the third color filter CF3, the first light-receiving color filter CF10, and the second light-receiving color filter CF20. The third light-receiving color filter CF30 may include an organic material, but is not limited thereto.

According to some embodiments, the wavelength of light incident on the first light-receiving element PD1, the second light-receiving element PD2, and the third light-receiving element PD3 may be controlled according to the types and arrangement of the first light-receiving color filter CF10, the second light-receiving color filter CF20, and the third light-receiving color filter CF30.

The third display region DA3 of the substrate 100 may be, for example, an illuminance sensing region. According to some embodiments, the first light-receiving color filter CF10, the second light-receiving color filter CF20, and the third light-receiving color filter CF30 may be provided on the third display region DA3 of the substrate 100 and respectively provided above the first light-receiving element PD1, the second light-receiving element PD2, and the third light-receiving element PD3. Accordingly, the light of the first wavelength, the light of the second wavelength, and the light of the third wavelength may be respectively incident on the first light-receiving element PD1, the second light-receiving element PD2, and the third light-receiving element PD3. Accordingly, the display apparatus 1 may obtain detection results regaring light of the different first to third wavelengths in the third display region DA3 of the substrate 100. Information about illuminance may be derived from the detection results.

Referring to FIGS. 1, 3, 5, and 6, light-emitting element groups may be located on the first display region DA1, the second display region DA2, and the third display region DA3 of the substrate 100. Each of the light-emitting element groups may include the first to third light-emitting elements ED1, ED2, and ED3.

The first light-receiving element PD1 may include a plurality of first light-receiving elements PD1. One of the plurality of first light-receiving elements PD1 may be arranged in the first display region DA1, another one of the plurality of first light-receiving elements PD1 may be arranged in the second display region DA2, and another one of the plurality of first light-receiving elements PD1 may be arranged in the third display region DA3.

The second light-receiving element PD2 may include a plurality of second light-receiving elements PD2. One of the plurality of second light-receiving elements PD2 may be arranged in the first display region DA1, and another one of the plurality of second light-receiving elements PD2 may be arranged in the second display region DA2. None of the plurality of second light-receiving elements PD2 may be located on the third display region DA3. The plurality of second light-receiving elements PD2 may be apart from the third display region DA3.

The third light-receiving element PD3 may be located on the third display region DA3 of the substrate 100, but may not be located on the first display region DA1 and the second display region DA2 of the substrate 100. The third light-receiving element PD3 may be apart from the first display region DA1 and the second display region DA2 of the substrate 100.

FIG. 6 illustrates that the first light-emitting element ED1, the second light-emitting element ED2, the third light-emitting element ED3, the first light-receiving element PD1, the second light-receiving element PD2, and the third light-receiving element PD3 are arranged in the first direction D1, but this is only an example, and the arrangement of the first to third light-emitting elements ED1, ED2, and ED3 and the first to third light-receiving elements PD1, PD2, and PD3 may be modified in various ways.

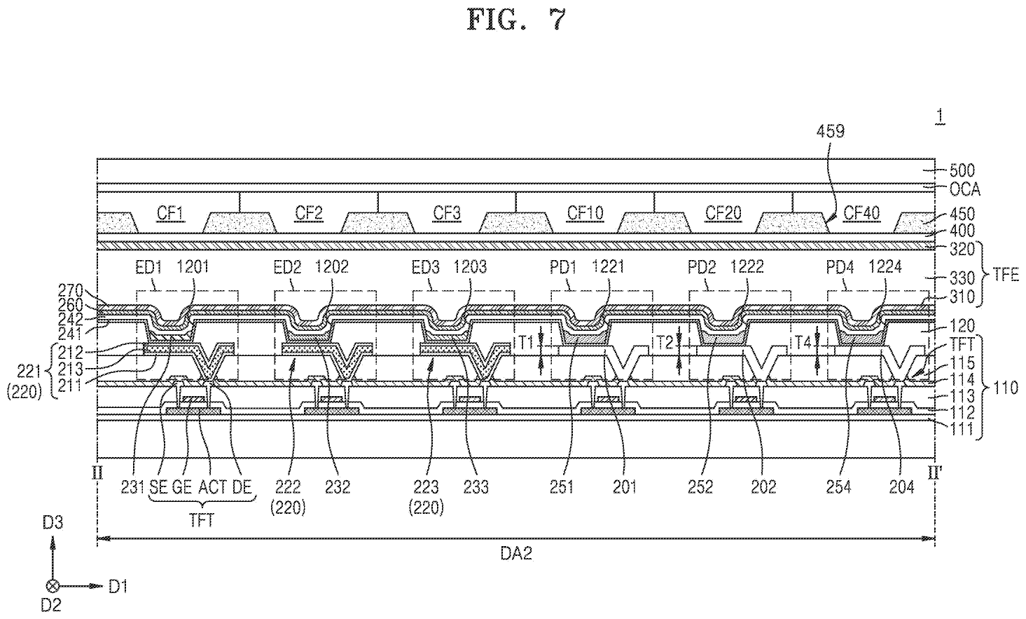

FIG. 7 is a schematic cross-sectional view of a display apparatus in a second display region of a substrate, according to some embodiments, and correspond to a cross section of the display apparatus of FIG. 1 taken along line II-II′ of FIG. 1. Hereinafter, redundant descriptions are omitted.

Referring to FIG. 7, the display apparatus 1 may include the substrate 100, the pixel-defining film 120, the first light-emitting element ED1, the second light-emitting element ED2, the third light-emitting element ED3, the first light-receiving element PD1, the second light-receiving element PD2, a fourth light-receiving element PD4, the first to third color filters CF1, CF2, and CF3, the first and second light-receiving color filters CF10 and CF20, and a fourth light-receiving color filter CF40.

The structures and arrangement of the first to third light-emitting elements ED1, ED2, and ED3, the first and second light-receiving elements PD1 and PD2, the first to third color filters CF1, CF2, and CF3, and the first and second light-receiving color filters CF10 and CF20 may be substantially the same as described in the example of FIG. 6.

The fourth light-receiving element PD4 may be located on the second display region DA2 of the substrate 100, and may be arranged next to the first to third light-emitting elements ED1, ED2, and ED3 and the first and second light-receiving elements PD1 and PD2. The fourth light-receiving element PD4 may be formed via a single process with the first light-receiving element PD1 and the second light-receiving element PD2. Accordingly, manufacturing of the display apparatus 1 may be simplified.

The fourth light-receiving element PD4 may include a fourth transparent light-receiving electrode 204, a fourth light-absorbing layer 254, and the opposite electrode 260. The fourth transparent light-receiving electrode 204 may be provided on the planarizing insulating layer 115. The fourth transparent light-receiving electrode 204 may be connected with one of the corresponding source electrode SE and drain electrode DE through the planarizing insulating layer 115. The fourth transparent light-receiving electrode 204 may be laterally apart from the first to third pixel electrodes 221, 222, and 223.

The fourth transparent light-receiving electrode 204 may have a structure identical to that of each of the first and second transparent light-receiving electrodes 201 and 202, and may include a material same as that of each of the first and second transparent light-receiving electrodes 201 and 202. A fourth thickness T4 of the fourth transparent light-receiving electrode 204 may be substantially equal to the first thickness T1 and the second thickness T2. The fourth thickness T4 may be about 70 Å to about 1,000 Å. The fourth transparent light-receiving electrode 204 may be formed via a single process with the first transparent light-receiving electrode 201 and the second transparent light-receiving electrode 202. The metal layer 213 of each of the first to third pixel electrodes 221, 222, and 223 may include a material different from that of the fourth transparent light-receiving electrode 204.

The pixel-defining film 120 may further have a fourth light-receiving opening 1224. The fourth light-receiving opening 1224 may expose at least a portion of an upper surface of the fourth transparent light-receiving electrode 204. The pixel-defining film 120 may cover an edge of the fourth transparent light-receiving electrode 204.

The fourth light-absorbing layer 254 may be located above the fourth transparent light-receiving electrode 204 and arranged in the fourth light-receiving opening 1224. The fourth light-absorbing layer 254 may include a material same as that of each of the first light-absorbing layer 251 and the second light-absorbing layer 252. The fourth light-absorbing layer 254 may be formed via a single process with the first light-absorbing layer 251 and the second light-absorbing layer 252. The fourth light-absorbing layer 254 may sense light by including a photodiode such as a white photodiode. The fourth light-absorbing layer 254 may include a material that senses the light of the first wavelength, the second wavelength, the third wavelength, and the fourth wavelength.

The opposite electrode 260 may extend onto the fourth light-absorbing layer 254. The opposite electrode 260 above the fourth light-absorbing layer 254 may be integrally formed with the opposite electrode 260 above the first to third emission layers 231, 232, and 233. For example, the opposite electrode 260 included in the fourth light-receiving element PD4 may be connected with the opposite electrode 260 included in the first light-emitting element ED1, the opposite electrode 260 included in the second light-emitting element ED2, and the opposite electrode 260 included in the third light-emitting element ED3 without boundaries. When the fourth light-receiving element PD4 includes the opposite electrode 260, it may indicate that the fourth light-receiving element PD4 includes a seventh portion of the opposite electrode 260.

The first common layer 241 may extend onto an inner wall of the fourth light-receiving opening 1224 and may be further provided between the fourth transparent light-receiving electrode 204 and the fourth light-absorbing layer 254. Accordingly, the fourth light-receiving element PD4 may further include a corresponding portion of the first common layer 241. The corresponding portion of the first common layer 241 may be provided between the fourth transparent light-receiving electrode 204 and the fourth light-absorbing layer 254.

The second common layer 242 may further extend onto an upper surface of the fourth light-absorbing layer 254. Accordingly, the fourth light-receiving element PD4 may further include a corresponding portion of the second common layer 242. The corresponding portion of the second common layer 242 may be provided between the fourth light-absorbing layer 254 and the opposite electrode 260.

The capping layer 270 may be vertically apart from the fourth light-absorbing layer 254 and may cover the upper surface of the opposite electrode 260.

According to some embodiments, the fourth light-receiving element PD4 may include the fourth transparent light-receiving electrode 204, but may not include a reflective electrode, a metal electrode, and a metal layer on a lower surface of the fourth light-absorbing layer 254. Accordingly, the fourth light-receiving element PD4 may have a non-resonant structure as described in the example of the first light-receiving element PD1. The fourth light-receiving element PD4 may absorb light in a relatively wide wavelength band. The light detection performance, sensing sensitivity, sensing reliability, and external quantum efficiency (EQE) characteristics of the fourth light-receiving element PD4 may be improved.

The fourth light-receiving color filter CF40 may be located above the fourth light-receiving element PD4. The fourth light-receiving color filter CF40 may transmit the light of the fourth wavelength. The fourth light-receiving color filter CF40 may be a near-infrared ray color filter. Among external light, light of a near-infrared ray wavelength may pass through the fourth light-receiving color filter CF40 and be incident on the fourth light-receiving element PD4. The fourth light-receiving element PD4 may absorb light in a relatively wide wavelength range. The fourth light-receiving element PD4 may detect incident near-infrared rays.

In order to sense information about a user's health, it may be further required to sense near-infrared rays as well as the light of the first wavelength and the light of the second wavelength. According to some embodiments, the fourth light-receiving element PD4 may sense near-infrared rays by using the fourth light-receiving color filter CF40 as a near-infrared ray color filter.

The fourth light-receiving element PD4 and the fourth light-receiving color filter CF40 may be further provided on the first display region DA1 of the substrate 100 of FIG. 3 and on the third display region DA3 of the substrate 100 of FIG. 5.

The display apparatus 1 may be modified in various ways. For example, FIGS. 3, 5, 6, and 7 illustrate that the pixel circuit layer 110 is located on lower surface of the first to third light-emitting elements ED1, ED2, and ED3, the first light-receiving element PD1, the second light-receiving element PD2, and the third light-receiving element PD3, but unlike shown, the pixel circuit layer 110 may be located on upper surfaces of the first to third light-emitting elements ED1, ED2, and ED3, the first light-receiving element PD1, the second light-receiving element PD2, and the third light-receiving element PD3. In this case, the display apparatus 1 may be a bottom-emission display apparatus.

A display apparatus according to some embodiments may include a transparent conductive layer to expand a wavelength band, in which a light-receiving element can absorb light, and relatively improve detection performance.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate;
light-emitting elements on the substrate;
a first light-receiving element on the substrate and arranged next to the light-emitting elements; and
a first light-receiving color filter on the first light-receiving element,
wherein the first light-receiving element comprises a first transparent light-receiving electrode, a first light-absorbing layer on the first transparent light-receiving electrode, and an opposite electrode on the first light-absorbing layer,
the first light-absorbing layer comprises a material that has sensitivity to light of a first wavelength, light of a second wavelength, and light of a third wavelength,
the first light-receiving color filter is configured to transmit the light of the first wavelength,
the light of the first wavelength is a first one from among green light, red light, and blue light,
the light of the second wavelength is a second one from among the green light, the red light, and the blue light, and
the light of the third wavelength is a third one from among the green light, the red light, and the blue light.

2. The display apparatus of claim 1, wherein the first light-receiving element does not comprise a metal layer and a reflective electrode, on a lower surface of the first light-absorbing layer.

3. The display apparatus of claim 1, wherein each of the light-emitting elements comprises a stack of a pixel electrode and an emission layer on the pixel electrode, and
the pixel electrode comprises a metal layer, and the metal layer comprises a material different from that of the first transparent light-receiving electrode.

4. The display apparatus of claim 3, wherein the opposite electrode extends onto an upper surface of the emission layer, and
a thickness of the first transparent light-receiving electrode is different from a thickness of the pixel electrode.

5. The display apparatus of claim 3, wherein the pixel electrode further comprises:
a lower transparent electrode on a lower surface of the metal layer; and
an upper transparent electrode on an upper surface of the metal layer.

6. The display apparatus of claim 1, further comprising:
a second light-receiving element next to the light-emitting elements; and
a second light-receiving color filter on the second light-receiving element and configured to transmit the light of the second wavelength,
wherein the second light-receiving element comprises a second transparent light-receiving electrode and a second light-absorbing layer on the second transparent light-receiving electrode.

7. The display apparatus of claim 6, wherein the second light-absorbing layer comprises a material that has sensitivity to the light of the first wavelength, the light of the second wavelength, and the light of the third wavelength.

8. The display apparatus of claim 6, wherein the second transparent light-receiving electrode comprises a material same as that of the first transparent light-receiving electrode.

9. The display apparatus of claim 6, wherein a thickness of the second transparent light-receiving electrode is equal to a thickness of the first transparent light-receiving electrode.

10. The display apparatus of claim 6, further comprising:
a third light-receiving element next to the light-emitting elements; and
a third light-receiving color filter on the third light-receiving element and configured to transmit the light of the third wavelength,
wherein the third light-receiving element comprises a third transparent light-receiving electrode and a third light-absorbing layer on the third transparent light-receiving electrode.

11. The display apparatus of claim 1, further comprising:
a fourth light-receiving element next to the light-emitting elements and comprising a fourth transparent light-receiving electrode and a fourth light-absorbing layer on the fourth transparent light-receiving electrode; and
a fourth light-receiving color filter on the fourth light-receiving element,
wherein the fourth light-absorbing layer has sensitivity to the light of the first wavelength, the light of the second wavelength, the light of the third wavelength, and near-infrared rays, and
the fourth light-receiving color filter transmits the near-infrared rays.

12. The display apparatus of claim 11, wherein the first light-absorbing layer has sensitivity to the near-infrared rays.

13. A display apparatus comprising:
a substrate;
a plurality of light-emitting elements on the substrate;
a first light-receiving element next to the light-emitting elements;
a second light-receiving element next to the light-emitting elements;
a first light-receiving color filter on the first light-receiving element; and
a second light-receiving color filter on the second light-receiving element and configured to transmit light of a wavelength different from that of the first light-receiving color filter,
wherein the first light-receiving element comprises a first transparent light-receiving electrode and a first light-absorbing layer on the first transparent light-receiving electrode,
the second light-receiving element comprises a second transparent light-receiving electrode and a second light-absorbing layer on the second transparent light-receiving electrode, and
the second light-absorbing layer comprises a material same as that of the first light-absorbing layer.

14. The display apparatus of claim 13, further comprising:
a planarizing insulating layer on the substrate; and
a pixel-defining film on the first and second transparent light-receiving electrodes,
wherein lower surfaces of the first and second transparent light-receiving electrodes are in physical contact with the planarizing insulating layer, and
upper surfaces of the first and second transparent light-receiving electrodes are in physical contact with the pixel-defining film.

15. The display apparatus of claim 13, wherein the substrate has a first display region and a second display region,
the light-emitting elements are on the first display region and the second display region of the substrate,
the first light-receiving element is on the first display region of the substrate, and
the second light-receiving element is on the second display region of the substrate.

16. The display apparatus of claim 15, wherein the first light-receiving element comprises a plurality of first light-receiving elements, and
at least one of the plurality of first light-receiving elements is on the first display region, and another one of the plurality of first light-receiving elements is provided on the second display region.

17. The display apparatus of claim 16, wherein the second light-receiving element is spaced apart from the first display region.

18. The display apparatus of claim 15, further comprising:
a third light-receiving element next to the light-emitting elements; and
a third light-receiving color filter on the third light-receiving element and configured to transmit light of a wavelength different from that of each of the first light-receiving color filter and the second light-receiving color filter,
wherein the substrate comprises a third display region, and
the third light-receiving element is on the third display region of the substrate.

19. The display apparatus of claim 18, wherein the third light-receiving element comprises a third transparent light-receiving electrode and a third light-absorbing layer on the third transparent light-receiving electrode, and
the third light-absorbing layer comprises a material same as that of each of the first light-absorbing layer and the second light-absorbing layer.

20. The display apparatus of claim 18, wherein the second light-receiving element comprises a plurality of second light-receiving elements,
at least one of the plurality of second light-receiving elements is on the second display region of the substrate,
another one of the plurality of second light-receiving elements is on the third display region of the substrate, and
the third light-receiving element is spaced apart from the first display region and the second display region of the substrate.
